(19) United States
(12) Patent Application Publication
(10) Pub. No.: US 2009/0291548 A1
(43) Pub. Date: Nov. 26, 2009

(54) METHOD FOR PREPARING P-TYPE POLYSILICON GATE STRUCTURE

(75) Inventors: YUAN MING CHANG, HSINCHU COUNTY (TW); CHENG DA WU, KEELUNG CITY (TW); DA YU CHUANG, CHANGHUA COUNTY (TW); YEN TA CHEN, CHANGHUA CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/124,101

(22) Filed: May 20, 2008

(51) Int. Cl. H01L 21/28

(52) U.S. Cl. 438/529; 257/E21.197; 257/E21.336

(57) ABSTRACT

A method for preparing a P-type polysilicon gate structure comprises the steps of forming a gate oxide layer on a substrate, forming an N-type polysilicon layer on the gate oxide layer, performing a first implanting process to convert the N-type polysilicon layer into a P-type polysilicon layer, performing a second implanting process to implant P-type dopants into a portion of the P-type polysilicon layer near the interface between the gate oxide layer and the P-type polysilicon layer, and performing a thermal treating process at a predetermined temperature for a predetermined period to complete the P-type polysilicon gate structure.

### BACKGROUND OF THE INVENTION

(A) Field of the Invention

The present invention relates to a method for preparing a P-type polysilicon gate structure, and more particularly, to a method for preparing a P-type polysilicon gate structure by using a double implanting technique to avoid poly depletion and boron penetration problems.

(B) Description of the Related Art

It is known that a complementary MOSFET (CMOS) consisting of NMOS and PMOS is a key part of the integrated circuit. With the size of electronic devices becoming smaller, a P-type polysilicon gate structure is required for imparting the PMOS with a surface channel, so as to avoid short channel effect. There are two methods for preparing the P-type polysilicon gate structure in the CMOS device. The first method is fabricating the NMOS and PMOS in the CMOS device individually; however, this method is rather complex since it requires two groups of masks and two groups of fabrication processes for the NMOS and PMOS, respectively.

The second method uses the counter doping technique, which requires implanting B/BF2 ions for converting N-type polysilicon into the P-type polysilicon gate structure. However, the fast diffusion of boron in polysilicon and within the gate oxide results in the easy penetration of boron through the gate to the underlying silicon substrate. Consequently, the counter doping process must implant the B/BF2 ions at very high dosage and very low energy to avoid boron penetration. However, the boron concentration will be lower at the interface between the gate oxide layer and the N-type polysilicon due to the normal distribution character of the implanting process, which causes a P-type poly depletion problem. In contrast, deeper or higher boron implanting can mitigate the P-type poly depletion problem, but then the boron penetration issue becomes more pronounced.

In view of the foregoing, there needs a method for fabricating advanced CMOS integrated circuits which prevents boron penetration through the thin gate oxide of P-channel devices, yet requires only minimal modification to the conventional CMOS fabrication process.

### SUMMARY OF THE INVENTION

One aspect of the present invention provides a method for preparing a P-type polysilicon gate structure by using a double implanting technique to avoid the poly depletion and boron penetration problems.

A method for preparing a P-type polysilicon gate structure according to this aspect of the present invention comprises the steps of forming a gate oxide layer on a substrate, forming an N-type polysilicon layer on the gate oxide layer, performing a first implanting process to convert the N-type polysilicon layer into a P-type polysilicon layer, performing a second implanting process with a lower dose and a slight deeper energy as compared to the first implanting process to implant P-type dopants into a portion of the P-type polysilicon layer near the interface between the gate oxide layer and the P-type polysilicon layer, and performing a thermal treating process at a predetermined temperature for a predetermined period to complete the P-type polysilicon gate structure.

Another aspect of the present invention provides a method for preparing a P-type polysilicon gate structure comprising the steps of forming a gate oxide layer on a substrate, forming an N-type polysilicon layer on the gate oxide layer, performing a first implanting process to implant P-type dopants into a portion of the N-type polysilicon layer near the interface between the gate oxide layer and the N-type polysilicon layer, performing a second implanting process to convert the N-type polysilicon layer into a P-type polysilicon layer, and performing a thermal treating process at a predetermined temperature for a predetermined period to complete the P-type polysilicon gate structure.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 to FIG. 4 illustrate a method for preparing a P-type polysilicon gate structure according to one embodiment of the present invention;

FIG. 5 illustrates a secondary ion mass spectrometry (SIMS) profile for concentrations of N-type dopants and P-type dopants in the P-type polysilicon gate structure according to the prior art;

FIG. 6 and FIG. 7 illustrate SIMS profiles for concentrations of N-type dopants and P-type dopants in the P-type polysilicon gate structure before and after the RTA process according to one embodiment of the present invention;

FIG. 8 and FIG. 9 illustrate SIMS profiles for concentrations of N-type dopants and P-type dopants in the P-type polysilicon gate structure before and after the RTA process according to another embodiment of the present invention;

FIG. 10 and FIG. 11 illustrate SIMS profiles for concentrations of N-type dopants and P-type dopants in the P-type polysilicon gate structure before and after the RTA process according to another embodiment of the present invention; and

FIG. 12 and FIG. 13 illustrate SIMS profiles for concentrations of N-type dopants and P-type dopants in the P-type polysilicon gate structure before and after the RTA process according to another embodiment of the present invention.

### DETAILED DESCRIPTION OF THE INVENTION

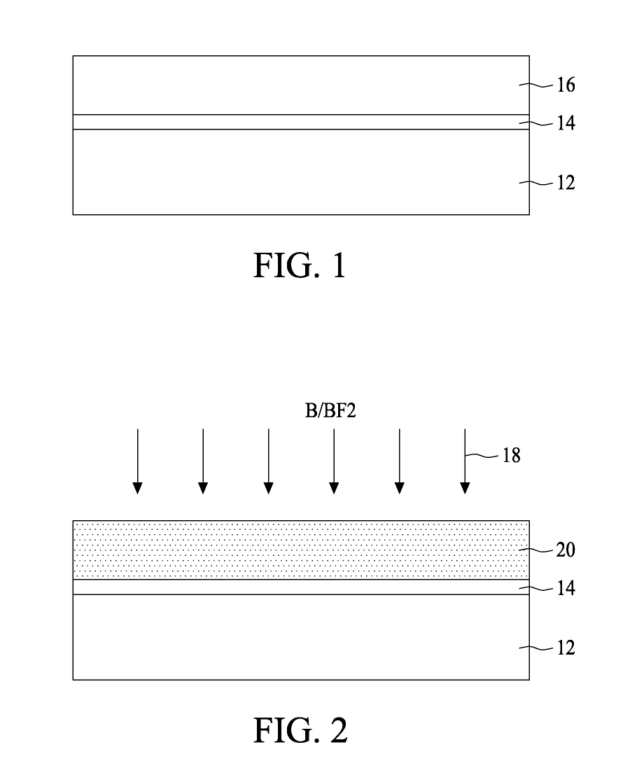

FIG. 1 to FIG. 4 illustrates a method for preparing a P-type polysilicon gate structure 10 according to one embodiment of the present invention. First, a thermal oxidation process is performed to form a gate oxide layer 14 on a substrate 12 such as a silicon substrate, and a deposition process is performed to form an N-type polysilicon layer 16 on the gate oxide layer 14. Subsequently, a first implanting process is performed to implant P-type dopants 18 such as B/BF2 ions into the N-type polysilicon layer 16 so as to convert the N-type polysilicon layer 16 into a P-type polysilicon layer 20, as shown in FIG. 2.

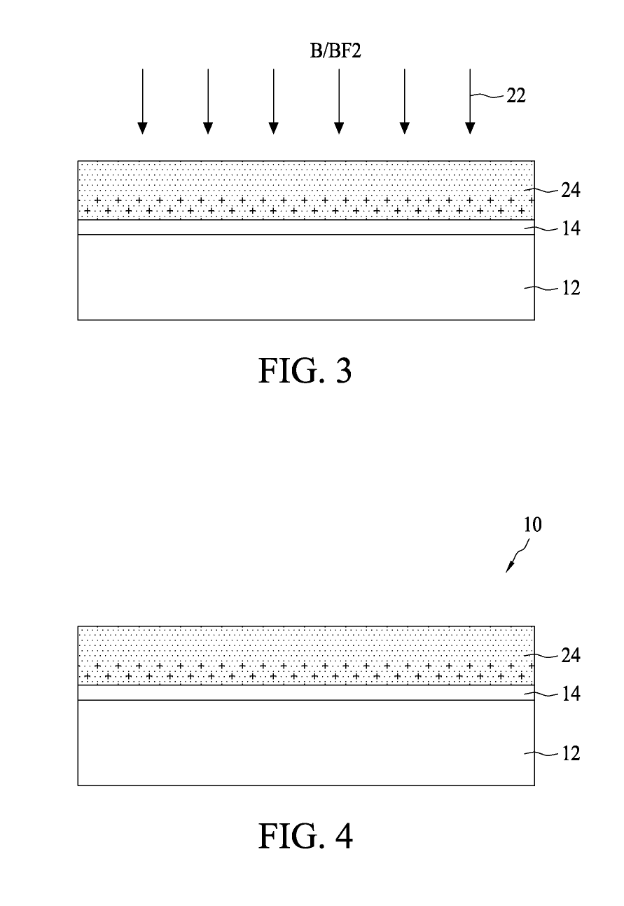

Referring to FIG. 3, a second implanting process to implant P-type dopants 22 such as B/BF2 into a portion of the P-type polysilicon layer 20 near the interface between the gate oxide layer 14 and the P-type polysilicon layer 20 to form a P-type polysilicon layer 24. The P-type dopants 22 can be the same as or different from the P-type dopants 18. Subsequently, a thermal treating process such as a rapid thermal annealing process (RTA) is performed at a predetermined temperature between 900° C. and 1100° C. for a predetermined period between 15 and 45 seconds to complete the P-type polysilicon gate structure 10, as shown in FIG. 4. In addition, the operation sequence of the first implanting process (counter doping) and the second implanting process (compensation doping) may be optionally reversed, i.e., performing the compensation doping before performing the counter doping.

The implanting dose of the first implanting process is higher than the implanting dose of the second implanting process, and the implanting energy of the first implanting process is slightly lower than the implanting energy of the second implanting process. For example, the implanting dose of the first implanting process is substantially between 1E16 ions/cm² and 4E16 ions/cm², while the implanting energy of the first implanting process is between 2 keV and 5 keV; the implanting dose of the second implanting process is between 8E14 ions/cm² and 2E15 ions/cm², and the implanting energy of the second implanting process is between 5 keV and 10 keV.

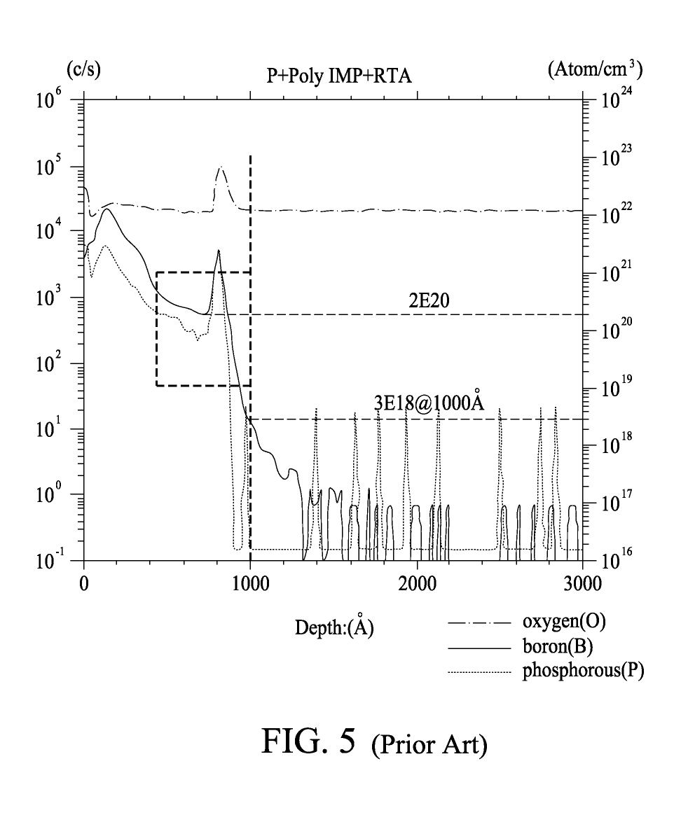

FIG. 5 illustrates a secondary ion mass spectrometry (SIMS) profile for concentrations of N-type dopants and P-type dopants in the P-type polysilicon gate structure according to the prior art. For this sample, the gate oxide thickness is 50 angstroms and the gate poly thickness is 900 angstroms. The conventional method uses the counter doping technique to convert N-type polysilicon into P-type polysilicon. However, the boron concentration (2E20 atoms/cm³) is substantially the same as the phosphorous concentration in the portion of the P-type polysilicon layer near the interface between the gate oxide layer and the P-type polysilicon, which causes the P-type poly depletion problem. In particular, the boron concentration at the interface with a depth of 1000 angstroms is about 3E18 atoms/cm³.

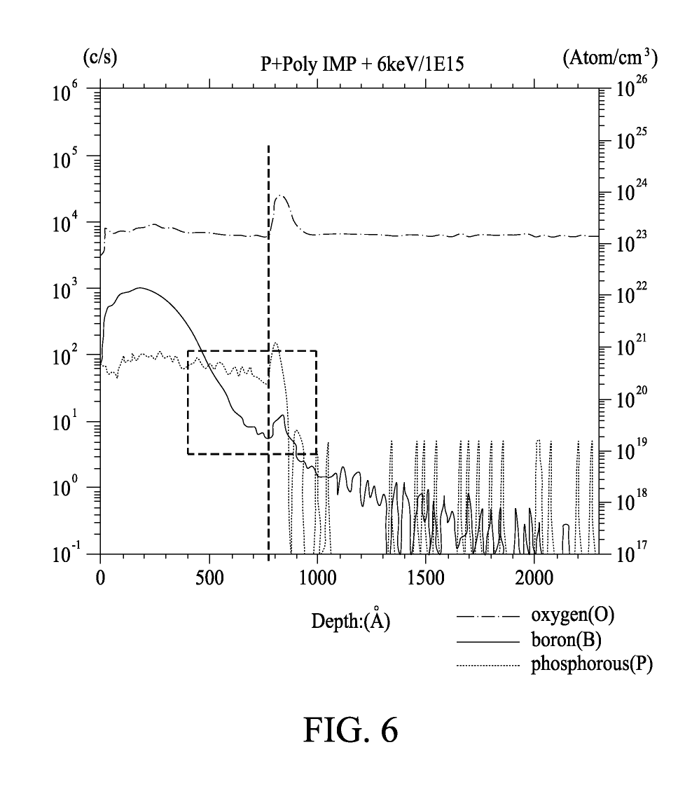

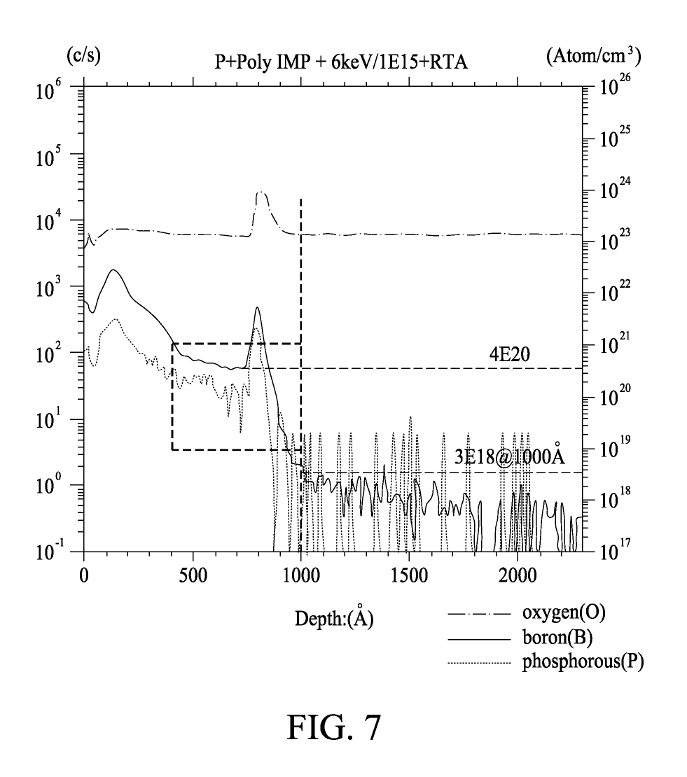

FIG. 6 and FIG. 7 illustrates SIMS profiles for concentrations of N-type dopants and P-type dopants in the P-type polysilicon gate structure 10 before and after the RTA process according to one embodiment of the present invention. In addition to the first implanting process (counter doping), which is the same as the counter doping technique in the prior art, this embodiment further performs the second implanting process (compensation doping) with an implanting dose of 1E15 atoms/cm² and implanting energy of 6 keV. After the RTA process, the boron concentration in the portion of the P-type polysilicon layer 24 near the interface is about 4E20 atoms/cm³, which is higher than the phosphorous concentration and twice as large as (200% of) the boron concentration (2E20 atoms/cm³) of the prior art in FIG. 5, i.e., the P-type carrier is more than the N-type carrier and there is no P-type poly depletion problem which compared to the prior art. In addition, the boron concentration at the interface with a depth of 1000 angstroms is about 3E18 atoms/cm³, which is the same as that in FIG. 5, i.e., there is no extra boron penetration problem as compared with the prior art in FIG. 5. In other words, the embodiment of the present invention can raise the boron concentration in P-type polysilicon without extra boron penetration risk.

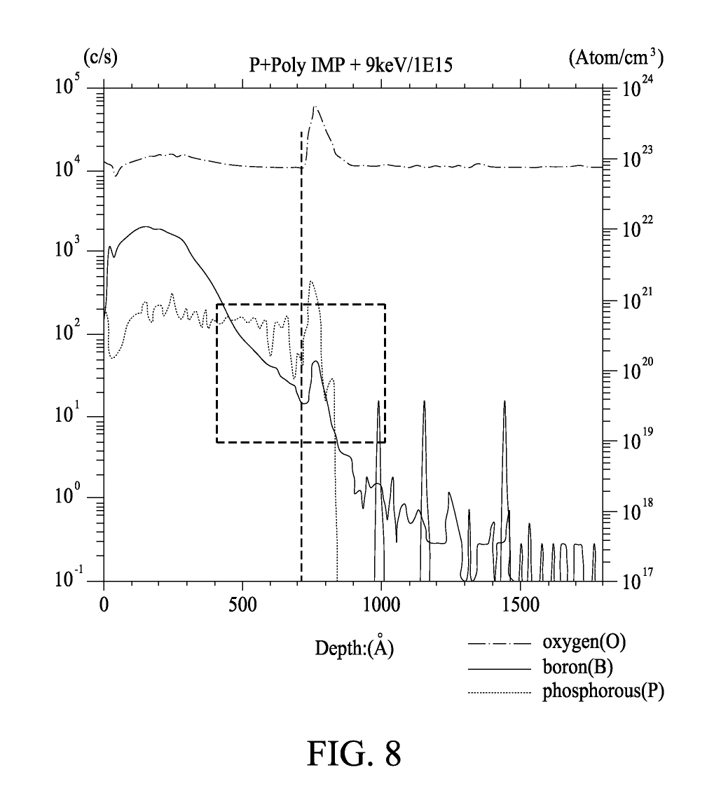

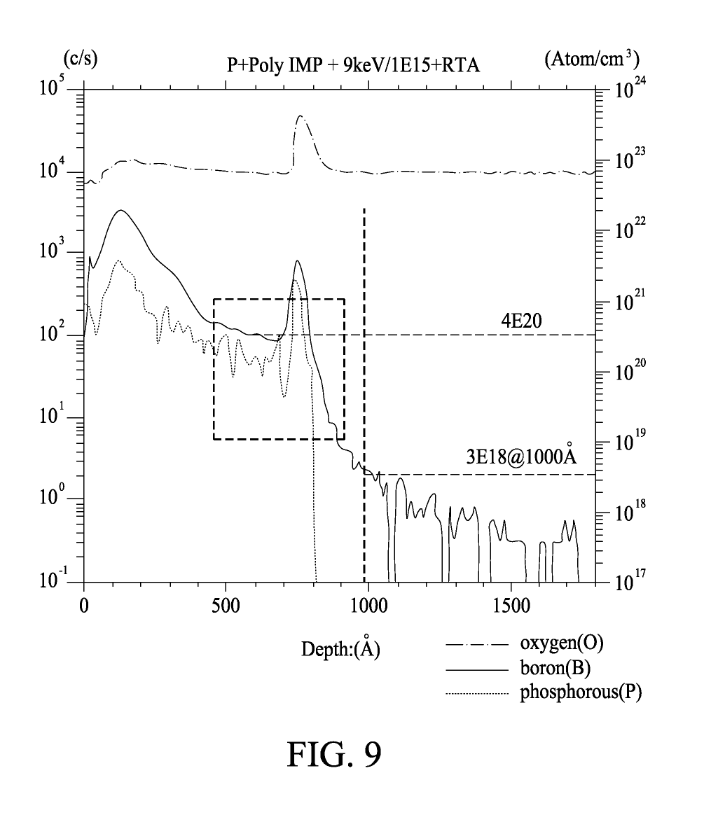

FIG. 8 and FIG. 9 illustrate SIMS profiles for concentrations of N-type dopants and P-type dopants in the P-type polysilicon gate structure 10 before and after the RTA process according to another embodiment of the present invention. In addition to the first implanting process (counter doping) the same as the counter doping technique in the prior art, this embodiment further performs the second implanting process (compensation doping) with an implanting dose of 1E15 atoms/cm² and implanting energy of 9 keV. After the RTA process, the boron concentration in the portion of the P-type polysilicon layer 24 near the interface is about 4E20 atoms/cm³, which is higher than the phosphorous concentration and twice as large as (200% of) the boron concentration (2E20 atoms/cm³) of the prior art in FIG. 5, i.e., the P-type carrier is more than the N-type carrier and there is no P-type poly depletion problem. In addition, the boron concentration at the interface with a depth of 1000 angstroms is about 3E18 atoms/cm³, which is the same as that in FIG. 5, i.e., no boron penetration problem as compared with the prior art in FIG. 5. In other words, the embodiment of the present invention can raise the boron concentration in P-type polysilicon without extra boron penetration risk.

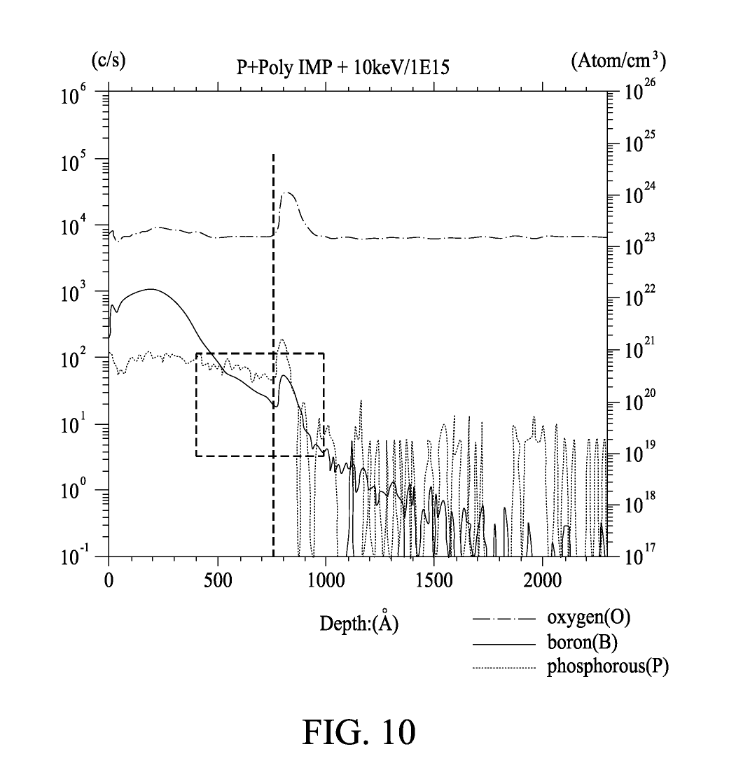

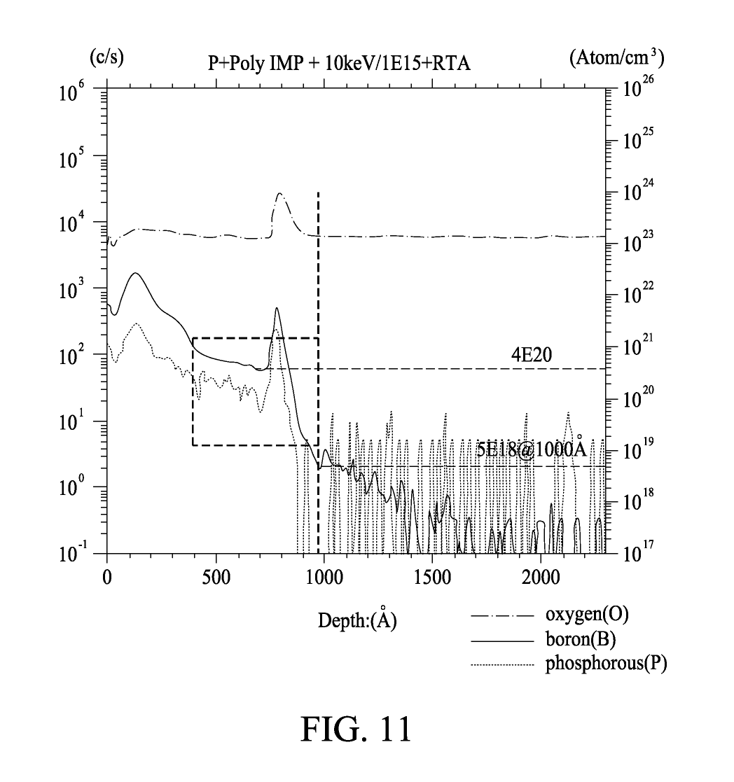

FIG. 10 and FIG. 11 illustrates SIMS profiles for concentrations of N-type dopants and P-type dopants in the P-type polysilicon gate structure 10 before and after the RTA process according to another embodiment of the present invention. In addition to the first implanting process (counter doping), which is the same as the counter doping technique in the prior art, this embodiment further performs the second implanting process (compensation doping) with an implanting dose of 1E15 atoms/cm² and implanting energy of 10 keV. After the RTA process, the boron concentration in the portion of the P-type polysilicon layer 24 near the interface is about 4E20 atoms/cm³, which is higher than the phosphorous concentration and twice as large as (200% of) the boron concentration (2E20 atoms/cm³) of the prior art in FIG. 5, i.e., the P-type carrier is more than the N-type carrier and there is no P-type poly depletion problem. In addition, the boron concentration at the interface with a depth of 1000 angstroms is about 5E18 atoms/cm³, which is slightly higher than that in FIG. 5 and there is slight boron penetration problem as compared with the prior art in FIG. 5. It bases on the device criteria for this application.

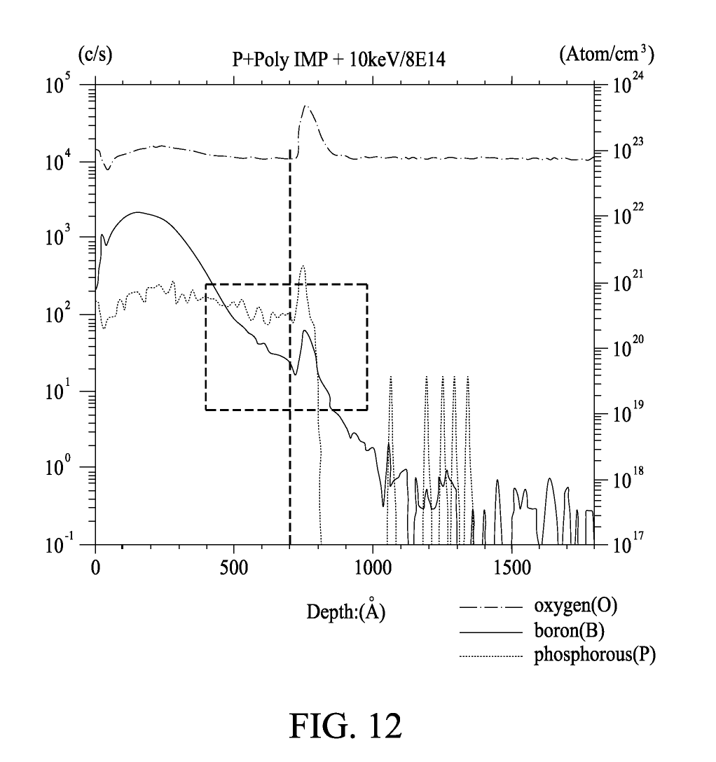

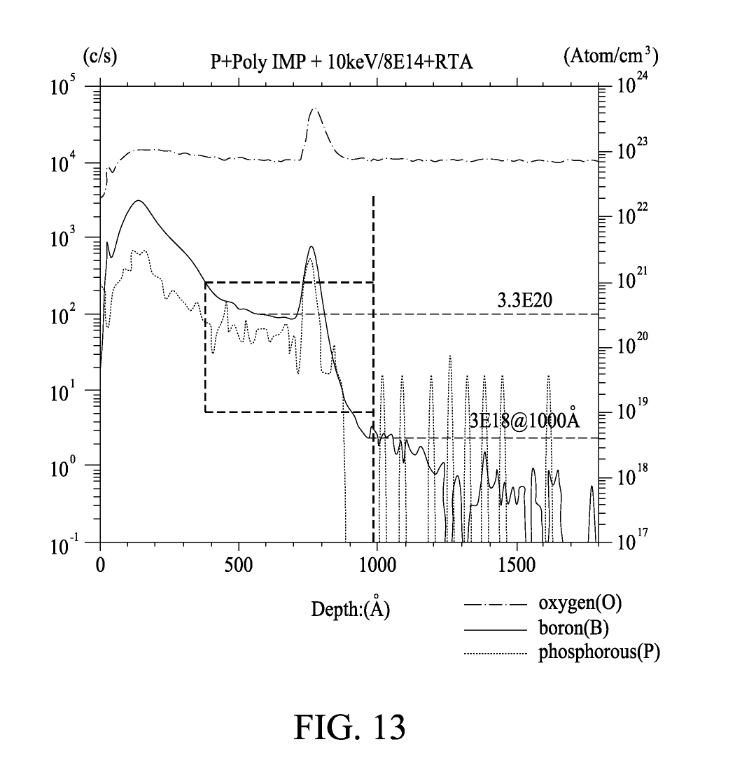

FIG. 12 and FIG. 13 illustrates SIMS profiles for concentrations of N-type dopants and P-type dopants in the P-type polysilicon gate structure 10 before and after the RTA process according to another embodiment of the present invention. In addition to the first implanting process (counter doping), which is the same as the counter doping technique in the prior art, this embodiment further performs the second implanting process (compensation doping) with an implanting dose of 8E14 atoms/cm² and implanting energy of 10 keV. After the RTA process, the boron concentration in the portion of the P-type polysilicon layer 24 near the interface is about 3.3E20 atoms/cm³, which is higher than the phosphorous concentration and 70% larger than (i.e., 170% of) the boron concentration (2E20 atoms/cm³) of the prior art in FIG. 5, i.e., the P-type carrier is more than the N-type carrier and there is no P-type poly depletion problem. In addition, the boron concentration at the interface with a depth of 1000 angstroms is about 3E18 atoms/cm³, which is the same as that in FIG. 5, i.e., there is no boron penetration problem as compared with the prior art in FIG. 5.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for preparing a P-type polysilicon gate structure, comprising the steps of:
forming a gate oxide layer on a substrate;
forming an N-type polysilicon layer on the gate oxide layer;
performing a first implanting process to convert the N-type polysilicon layer into a P-type polysilicon layer;
performing a second implanting process to implant P-type dopants into a portion of the P-type polysilicon layer near the interface between the gate oxide layer and the P-type polysilicon layer; and
performing a thermal treating process at a predetermined temperature for a predetermined period.

2. The method for preparing a P-type polysilicon gate structure of claim 1, wherein the implanting dose of the first implanting process is higher than the implanting dose of the second implanting process.

3. The method for preparing a P-type polysilicon gate structure of claim 1, wherein the implanting energy of the first implanting process is lower than the implanting energy of the second implanting process.

4. The method for preparing a P-type polysilicon gate structure of claim 1, wherein the first implanting process uses the same P-type dopants as the second implanting process.

5. The method for preparing a P-type polysilicon gate structure of claim 1, wherein the first implanting process uses P-type dopants different from those used in the second implanting process.

6. The method for preparing a P-type polysilicon gate structure of claim 1, wherein the implanting dose of the first implanting process is substantially between 1E16 ions/cm² and 4E16 ions/cm².

7. The method for preparing a P-type polysilicon gate structure of claim 1, wherein the implanting energy of the first implanting process is substantially between 2 keV and 5 keV.

8. The method for preparing a P-type polysilicon gate structure of claim 1, wherein the implanting dose of the second implanting process is substantially between 8E14 ions/cm² and 2E15 ions/cm².

9. The method for preparing a P-type polysilicon gate structure of claim 1, wherein the implanting energy of the second implanting process is substantially between 5 keV and 10 keV.

10. The method for preparing a P-type polysilicon gate structure of claim 1, wherein the predetermined temperature is substantially between 900° C. and 1100° C., and the predetermined period is substantially between 15 and 45 seconds.

11. A method for preparing a P-type polysilicon gate structure, comprising the steps of:
forming a gate oxide layer on a substrate;
forming an N-type polysilicon layer on the gate oxide layer;
performing a first implanting process to implant P-type dopants into a portion of the N-type polysilicon layer near the interface between the gate oxide layer and the N-type polysilicon layer;
performing a second implanting process to convert the N-type polysilicon layer into a P-type polysilicon layer; and
performing a thermal treating process at a predetermined temperature for a predetermined period.

12. The method for preparing a P-type polysilicon gate structure of claim 11, wherein the implanting dose of the second implanting process is higher than the implanting dose of the first implanting process.

13. The method for preparing a P-type polysilicon gate structure of claim 11, wherein the implanting energy of the second implanting process is lower than the implanting energy of the first implanting process.

14. The method for preparing a P-type polysilicon gate structure of claim 11, wherein the second implanting process uses the same P-type dopants as the first implanting process.

15. The method for preparing a P-type polysilicon gate structure of claim 11, wherein the second implanting process uses P-type dopants different from those used in the first implanting process.

16. The method for preparing a P-type polysilicon gate structure of claim 11, wherein the implanting dose of the second implanting process is substantially between 1E16 ions/cm² and 4E16 ions/cm².

17. The method for preparing a P-type polysilicon gate structure of claim 11, wherein the implanting energy of the second implanting process is substantially between 2 keV and 5 keV.

18. The method for preparing a P-type polysilicon gate structure of claim 11, wherein the implanting dose of the first implanting process is substantially between 8E14 ions/cm² and 2E15 ions/cm².

19. The method for preparing a P-type polysilicon gate structure of claim 11, wherein the implanting energy of the first implanting process is substantially between 5 keV and 10 keV.

20. The method for preparing a P-type polysilicon gate structure of claim 11, wherein the predetermined temperature is substantially between 900° C. and 1100° C., and the predetermined period is substantially between 15 and 45 seconds.
